(19) United States
(12) Patent Application Publication
(10) Pub. No.: US 2026/0123377 A1
(43) Pub. Date: Apr. 30, 2026

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: HYUNSOO CHUNG, Suwon-si (KR); HYEJIN KIM, Suwon-si (KR); KEUM-HEE MA, Suwon-si (KR)

(73) Assignee: SAMSUNG ELECTRONICS CO., LTD., Suwon-si (KR)

(21) Appl. No.: 19/201,288

(22) Filed: May 7, 2025

(30) Foreign Application Priority Data
Oct. 28, 2024 (KR) 10-2024-0148699

(51) Int. Cl. H01L 23/00; H01L 23/48; H01L 25/16

(52) U.S. Cl. CPC H10W 20/20; H10W 90/00; H10W 72/354; H10W 74/15; H10W 90/28; H10W 90/722; H10W 90/732

(57) ABSTRACT

A semiconductor package includes a first semiconductor chip and a second semiconductor chip sequentially stacked, a first bump structure between the first and second semiconductor chips and connecting the first and second semiconductor chips, a first bump protection layer extending in a first direction between the first and second semiconductor chips and covering a side surface of the first bump structure, and a first adhesive layer between the first bump protection layer and the first semiconductor chip, wherein the first semiconductor chip includes a first upper conductive pad having a first edge portion inserted into the first bump structure, the first adhesive layer extends to cover a sidewall of the first upper conductive pad that is not inserted into the first bump structure, and a first thickness of the first upper conductive pad is greater than a second thickness of the first adhesive layer.

### CROSS-REFERENCE TO RELATED APPLICATION

This application claims priority under 35 U.S.C. § 119 to Korean Patent Application No. 10-2024-0148699, filed on Oct. 28, 2024, in the Korean Intellectual Property Office, the disclosure of which is herein incorporated by reference in its entirety.

### BACKGROUND

One or more example embodiments of the disclosure relate to a semiconductor package and a method of manufacturing the same.

A semiconductor package is provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. With the development of electronic industry, various studies are being conducted to improve the reliability and durability of semiconductor packages.

### SUMMARY

An object of the disclosure is to provide a semiconductor package with improved reliability.

An object of the disclosure is to provide a method of manufacturing a semiconductor package with improved reliability.

The problem to be solved by the disclosure is not limited to the problems mentioned above, and other problems not mentioned may be clearly understood by those skilled in the art from the description below.

According to an aspect of an example embodiment of the disclosure, provided is a semiconductor package including: a first semiconductor chip and a second semiconductor chip sequentially stacked, a first bump structure between the first semiconductor chip and the second semiconductor chip and connecting the first semiconductor chip and the second semiconductor chip, a first bump protection layer extending in a first direction between the first semiconductor chip and the second semiconductor chip and covering a side surface of the first bump structure, and a first adhesive layer between the first bump protection layer and the first semiconductor chip, wherein the first semiconductor chip includes a first upper conductive pad having a first edge portion inserted into the first bump structure, the first adhesive layer extends to cover a sidewall of the first upper conductive pad that is not inserted into the first bump structure, and a first thickness of the first upper conductive pad is greater than a second thickness of the first adhesive layer.

A semiconductor package according to some embodiments of the disclosure includes a first semiconductor chip and a second semiconductor chip sequentially stacked, a first bump protection layer between the first semiconductor chip and the second semiconductor chip and extending in a first direction, a first bump structure between the first semiconductor chip and the second semiconductor chip and connecting the first semiconductor chip and the second semiconductor chip by penetrating the first bump protection layer, and a first adhesive layer between the first bump protection layer and the first semiconductor chip, wherein the first semiconductor chip includes a first substrate including a first front surface and a first back surface that are opposite to each other, a first upper conductive pad on the first back surface, and a first lower conductive pad on the first front surface, the second semiconductor chip includes a second substrate including a second front surface and a second back surface that are opposite to each other, and a second lower conductive pad on the second front surface, the first bump structure includes a first solder pattern connected to the first upper conductive pad, and a first metal pattern on the first solder pattern and connected to the second lower conductive pad, a first edge portion of the first upper conductive pad is inserted into the first solder pattern, and a second edge portion of the first solder pattern adjacent to the first substrate is spaced apart from the first edge portion in the first direction and is positioned at a lower level than that of the first edge portion.

A semiconductor package according to some embodiments of the disclosure includes semiconductor chips sequentially stacked, a molding member covering the semiconductor chips, a bump structure between the semiconductor chips and connecting the semiconductor chips, a bump protection layer covering a side surface of the bump structure, and an adhesive layer between the bump protection layer and a corresponding semiconductor chip, wherein each of the semiconductor chips includes a substrate including a front surface and a back surface opposite to each other, a lower conductive pad on the front surface, a through-via penetrating the substrate, and an upper conductive pad on the back surface and connected to the through-via, the bump structure connects the upper conductive pad and the lower conductive pad that are adjacent to each other, an upper portion of the upper conductive pad is partially inserted into the bump structure, and the bump protection layer includes at least one of an epoxy resin, an insulating resin, and a thermosetting resin.

A method of manufacturing a semiconductor package according to some embodiments of the disclosure includes forming a first upper conductive pad on a first back surface of a first substrate wafer, the first substrate wafer including a first front surface and the first back surface opposite to each other, forming a first adhesive layer covering a sidewall of the first upper conductive pad and the first back surface, forming a second lower conductive pad on a second front surface of a second substrate wafer, the second substrate wafer including the second front surface and a second back surface opposite to each other, forming a bump structure bonded to the second lower conductive pad, and a bump protection layer covering the bump structure and the second front surface of the second substrate wafer, removing a portion of a first surface of the bump protection layer and a portion of the bump structure to expose a second surface of the bump structure, turning over the second substrate wafer and removing a portion of the second back surface to form a second upper conductive pad, forming a second adhesive layer covering a sidewall of the second upper conductive pad and the second back surface, and dividing the second substrate wafer into a plurality of first chip structures by a dicing process.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of a semiconductor package according to one or more embodiments of the disclosure.

FIG. 2 is a cross-sectional view of FIG. 1 taken along line A-A′ according to one or more embodiments of the disclosure.

FIG. 3 is an enlarged view of portion ‘E1’ of FIG. 2.

FIGS. 4A and 4B illustrate plan views of a first upper conductive pad and a first solder pattern according to one or more embodiments of the disclosure.

FIGS. 5A and 5B are enlarged views of portion ‘E2’ of FIG. 2.

FIGS. 6A to 6G are cross-sectional views sequentially illustrating a process of manufacturing a first chip structure according to one or more embodiments of the disclosure.

FIGS. 7A to 7E are cross-sectional views sequentially illustrating a process of manufacturing a semiconductor package of FIG. 2 according to one or more embodiments of the disclosure.

FIG. 8 is an enlarged view of portion ‘E3’ of FIG. 7C.

FIG. 9 is a cross-sectional view taken along line A-A′ of FIG. 1 according to one or more embodiments of the disclosure.

FIG. 10 is an enlarged view of portion ‘E4’ of FIG. 9.

FIGS. 11A to 11G are cross-sectional views sequentially illustrating a process of manufacturing a second chip structure according to one or more embodiments of the disclosure.

FIG. 12 is an enlarged view of portion ‘E5’ of FIG. 11F.

FIGS. 13A to 13D are cross-sectional views sequentially illustrating a process of manufacturing a semiconductor package of FIG. 9 according to one or more embodiments of the disclosure.

FIG. 14 is an enlarged view of portion ‘E6’ of FIG. 13B.

FIG. 15 is a cross-sectional view of a semiconductor package according to one or more embodiments of the disclosure.

### DETAILED DESCRIPTION

Hereinafter, to explain the disclosure in detail, example embodiments according to the disclosure will be described with reference to the attached drawings.

Unless otherwise specified, in this specification, terms such as ‘upper portion,’‘upper surface,’ ‘lower portion,’ ‘lower surface,’ ‘side,’ ‘side surface’ and the like are based on the drawings, and actually, may vary depending on the direction in which the components are disposed.

Additionally, ordinal numbers such as “first,” “second,” “third,” etc. may be used as labels for specific elements, steps, directions, etc. to distinguish various elements, steps, directions, etc. from each other. Terms that are not described using “first,” “second,” etc. in the specification may still be referred to as “first” or “second” in the claims. Additionally, terms (for example, “first” in a specific claim) referenced by a specific ordinal number may be described elsewhere with a different ordinal number (for example, “second” in the specification or another claim).

Expressions such as “at least one of”, when preceding a list of elements, modify the entire list of elements and do not modify the individual elements of the list. For example, the expression, “at least one of a, b, and c” (or “at least one of a, b, or c”) should be understood as including only a, only b, only c, both a and b, both a and c, both b and c, or all of a, b, and c.

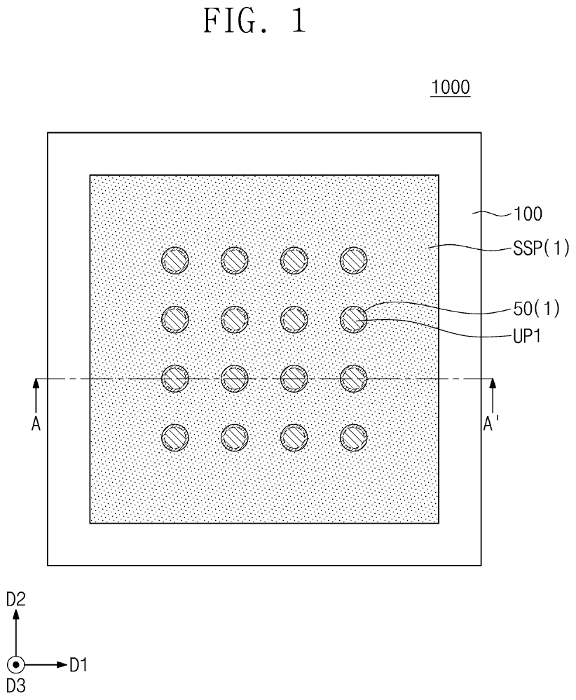

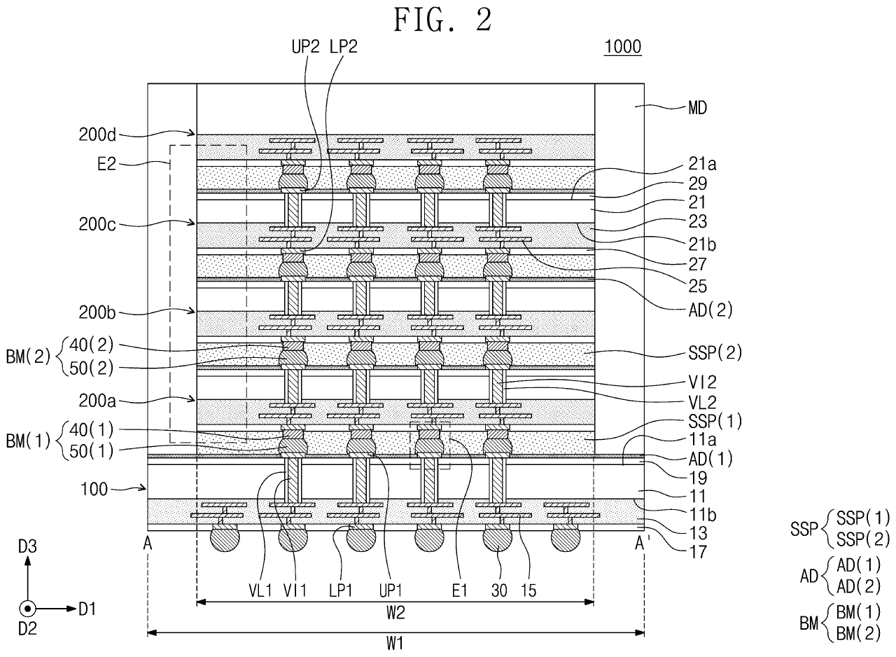

FIG. 1 is a plan view of a semiconductor package according to one or more embodiments of the disclosure. FIG. 2 is a cross-sectional view of FIG. 1 taken along line A-A′ according to one or more embodiments of the disclosure.

Referring to FIGS. 1 and 2, a semiconductor package 1000 according to one or more embodiments may include first to fifth semiconductor chips 100, 200a to 200d that are sequentially stacked, bump structures BM that are disposed between the first to fifth semiconductor chips 100, 200a to 200d and connect the first to fifth semiconductor chips 100, 200a to 200d, bump protection layers SSP between the first to fifth semiconductor chips 100, 200a to 200d, and a molding member MD that covers the first to fifth semiconductor chips 100, 200a to 200d, the bump structures BM, and the bump protection layers SSP. Each of the first to fourth semiconductor chips 100, 200a to 200c may include an adhesive layer AD disposed on a back surface thereof. A first width W1 of the first semiconductor chip 100 in a first direction D1 may be greater than a second width W2 of the second to fifth semiconductor chips 200a, 200b, 200c, and 200d in the first direction D1.

The first semiconductor chip 100 may be, for example, a logic circuit chip. The first semiconductor chip 100 may operate as an interface circuit between the second to fifth semiconductor chips 200a to 200d and an external controller. The first semiconductor chip 100 may receive commands, data, signals, etc. transmitted from an external controller and transmit the received commands, data, signals, etc. to the second to fifth semiconductor chips 200a to 200d. Alternatively, although not illustrated, the first semiconductor chip 100 may be a buffer chip or an interposer die that does not include a transistor. The first semiconductor chip 100 may be a different type of chip from the second to fifth semiconductor chips 200a, 200b, 200c, and 200d.

The second to fifth semiconductor chips 200a to 200d may be sequentially stacked on the first semiconductor chip 100. The second to fifth semiconductor chips 200a to 200d may be the same memory chips. The memory chip of the second to fifth semiconductor chips 200a to 200d may be, for example but not limited to, a dynamic random access memory (DRAM), a NAND Flash, a static RAM (SRAM), a magnetic RAM (MRAM), a phase-change RAM (PRAM), or a resistive RAM (RRAM). A width of the first semiconductor chip 100 may be greater than widths of the second to fifth semiconductor chips 200a to 200d. In one or more embodiments, a structure in which one logic circuit chip and four memory chips are stacked is disclosed, but a number of stacked logic circuit chips and memory chips is not limited thereto and may be variously changed. For example, eight or more memory chips may be stacked.

The first semiconductor chip 100 may include a first substrate 11 and a first interlayer insulating layer 13. The first substrate 11 may have a first back surface 11a and a first front surface 11b that are opposite to each other. Transistors (not shown) and first wiring lines 15 may be disposed on the first front surface 11b of the first substrate 11. The first interlayer insulating layer 13 may cover the first front surface 11b of the first substrate 11 and the first wiring lines 15. A first frontside protection layer 17 may cover a lower surface of the first interlayer insulating layer 13. A first backside protection layer 19 may cover the first back surface 11a of the first substrate 11.

Each of the second semiconductor chip 200a, the third semiconductor chip 200b, the fourth semiconductor chip 200c, and the fifth semiconductor chip 200d may include a second substrate 21 and a second interlayer insulating layer 23. The second substrate 21 may have a second back surface 21a and a second front surface 21b that are opposite to each other. Transistors (not shown) and second wiring lines 25 may be disposed on the second front surface 21b of the second substrate 21. The second interlayer insulating layer 23 may cover the second front surface 21b and the second wiring lines 25 of the second substrate 21. A second frontside protection layer 27 may cover a lower surface of the second interlayer insulating layer 23. A second backside protection layer 29 may cover the second back surface 21a of the second substrate 21. The fifth semiconductor chip 200d may not include the second backside protection layer 29.

The first and second substrates 11 and 21 may be wafer-level semiconductor substrates formed of a semiconductor such as silicon (Si). For example, the first and second substrates 11 and 21 may be silicon single-crystal substrates or silicon on insulator (SOI) substrates, respectively. The first and second interlayer insulating layers 13 and 23 may include at least one single layer or multiple layers that may include, for example, one or more of a silicon oxide layer, a silicon nitride layer, a silicon oxynitride layer, and a porous insulating layer. The first and second wiring lines 15 and 25 may have a single-layer or multi-layer structure including, for example, at least one of copper, aluminum, tungsten, titanium, titanium nitride, tantalum, tantalum nitride, ruthenium, and iridium. The first and second frontside protection layers 17 and 27 and the first and second backside protection layers 19 and 29 may include, for example, at least one of silicon oxide, silicon nitride, and silicon carbon nitride.

The first semiconductor chip 100 may include first through-vias VI1. Each of the second semiconductor chip 200a, the third semiconductor chip 200b, and the fourth semiconductor chip 200c may include second through-vias VI2. The fifth semiconductor chip 200d may not include the second through-via VI2. The first and second through-vias VI1 and VI2 may respectively penetrate the first and second substrates 11 and 21 of the first semiconductor chip 100, the second semiconductor chip 200a, the third semiconductor chip 200b, and the fourth semiconductor chip 200c, and may be respectively arranged at centers of the corresponding semiconductor chips 100, 200a to 200d. The first and second wiring lines 15 and 25 may be connected to the first and second through-vias VI1 and VI2 penetrating the corresponding semiconductor chips 100, 200a to 200d, respectively.

First and second via insulating layers VL1 and VL2 may be interposed between the first and second through-vias VI1 and VI2 and the first and second substrates 11 and 21, respectively. The first and second through-vias VI1 and VI2 may include a metal such as copper, aluminum, or tungsten. The first and second via insulating layers VL1 and VL2 may have a single-layer or multi-layer structure including, for example, at least one of silicon oxide, silicon nitride, and silicon oxynitride. Each of the first and second via insulating layers VL1 and VL2 may include an air gap region.

First upper conductive pads UP1 may be disposed on the first back surface 11a of the first semiconductor chip 100. The first upper conductive pads UP1 may be connected to the first through-via VI1, respectively. First lower conductive pads LP1 may be disposed on the first front surface 11b of the first semiconductor chip 100. The first lower conductive pads LP1 may be connected to the first wiring lines 15, respectively, and the first lower conductive pads LP1 may be electrically connected to the first through-via VI1, respectively. First connection members 30 may be bonded to the first lower conductive pads LP1, respectively. The first connection members 30 may include at least one of a copper bump, a copper pillar, and a solder ball, for example.

Second upper conductive pads UP2 may be disposed on the second back surface 21a of each of the second to fourth semiconductor chips 200a to 200c, respectively. The fifth semiconductor chip 200d may not include the second upper conductive pads UP2. Each of the second upper conductive pads UP2 may be connected to the second through-via VI2. Second lower conductive pads LP2 may be disposed on the second front surface 21b of each of the second to fifth semiconductor chips 200a to 200d, respectively. The second lower conductive pads LP2 may be connected to the second wiring lines 25, respectively, and the second lower conductive pads LP2 may be electrically connected to the second through-vias VI2, respectively. Each of the first and second upper conductive pads UP1 and UP2 and the first and second lower conductive pads LP1 and LP2 may include at least one metal among, for example, copper (Cu), gold (Au), nickel (Ni), tin (Sn), silver (Ag), tungsten (W), and aluminum (Al).

Each of the bump structures BM may include a solder pattern 50 and a metal pattern 40 thereon. The bump structures BM may include first bump structures BM(1) and second bump structures BM(2). A plurality of solder patterns 50 may be provided. The solder patterns 50 may include first solder patterns 50(1) and second solder patterns 50(2). A plurality of metal patterns 40 may be provided. The metal patterns 40 may include first metal patterns 40(1) and second metal patterns 40(2).

The first bump structures BM(1) may be disposed between the first semiconductor chip 100 and the second semiconductor chip 200a. The first bump structures BM(1) may be spaced apart from each other in the first direction D1 and a second direction D2. The first bump structures BM(1) may electrically connect the first upper conductive pads UP1 of the first semiconductor chip 100 and the second lower conductive pads LP2 of the second semiconductor chip 200a. Each of the first bump structures BM(1) may include a first solder pattern 50(1) disposed on the first upper conductive pad UP1 and a first metal pattern 40(1) disposed on the first solder pattern 50(1).

The second bump structures BM(2) may be disposed between the second to fifth semiconductor chips 200a to 200d, respectively. The second bump structures BM(2) may be spaced apart from each other in the first direction D1 and the second direction D2. The second bump structures BM(2) may electrically connect the second upper conductive pads UP2 and the second lower conductive pads LP2 of the second to fifth semiconductor chips 200a to 200d, respectively. The second bump structures BM(2) may include a second solder pattern 50(2) disposed on the second upper conductive pads UP2, and a second metal pattern 40(2) disposed on the second solder pattern 50(2).

Although not illustrated, one or more metal patterns, such as an under bump metallurgy (UBM), a barrier layer, an adhesive layer, a wetting layer, and/or an antioxidant, may be disposed in the first and second metal patterns 40(1) and 40(2). The first and second metal patterns 40(1) and 40(2) may include a conductive material, for example, a metal. The first and second metal patterns 40(1) and 40(2) may include, for example, copper or nickel. The first and second solder patterns 50(1) and 50(2) may include, for example but not limited to, nickel (Ni), tin (Sn), silver (Ag), or gold (Au). The first and second solder patterns 50(1) and 50(2) may include, for example for example but not limited to, SnAg.

The bump protection layers SSP may include a first bump protection layer SSP(1) and second bump protection layers SSP(2). The first bump protection layer SSP(1) may be interposed between the first semiconductor chip 100 and the second semiconductor chip 200a. The first bump protection layer SSP(1) may extend in the first direction D1. The first bump protection layer SSP(1) may cover a side surface of the first bump structures BM(1) and may protect the first bump structures BM(1). The first bump protection layer SSP(1) may have a second width W2 that is the same as that of the second semiconductor chip 200a in the first direction D1.

The second bump protection layers SSP(2) may be interposed between the second to fifth semiconductor chips 200a to 200d, respectively. The second bump protection layer SSP(2) may extend in the first direction D1. The second bump protection layer SSP(2) may cover a side surface of the second bump structures BM(2) and may protect the second bump structures BM(2). The second bump protection layer SSP(2) may have a second width W2 that is the same as that of the second semiconductor chip 200a in the first direction D1.

The first and second bump protection layers SSP(1) and SSP(2) may have a melting point higher than melting points of the first and second bump structures BM(1) and BM(2). The first and second bump protection layers SSP(1) and SSP(2) may include, for example, at least one of an epoxy resin, an insulating resin, or a thermosetting resin.

A plurality of adhesive layers AD may be provided. The plurality of adhesive layers AD may include a first adhesive layer AD(1) and second adhesive layers AD(2).

The first adhesive layer AD(1) may be interposed between the first bump protection layer SSP(1) and the first semiconductor chip 100. The first adhesive layer AD(1) may have a first width W1 that is the same as that of the first semiconductor chip 100 in the first direction D1. The first adhesive layer AD(1) may cover the first backside protection layer 19.

The second adhesive layer AD(2) may be interposed between the second bump protection layer SSP(2) and each of the second to fourth semiconductor chips 200a to 200c. The second adhesive layer AD(2) may have a second width W2 that is the same as the second to fourth semiconductor chips 200a to 200c in the first direction D1. The first adhesive layer AD(1) may cover the second backside protection layer 29.

The first and second adhesive layers AD(1) and AD(2) may include at least one of, for example but not limited to, an epoxy resin, an acrylic polymer, or silicone.

A molding member MD may cover an upper surface of the first semiconductor chip 100 and the side surfaces of the second to fifth semiconductor chips 200a to 200d. The molding member MD may include, for example but not limited to, an insulating resin such as an epoxy molding compound (EMC). The molding member MD may further include a filler, and the filler may be dispersed in the insulating resin.

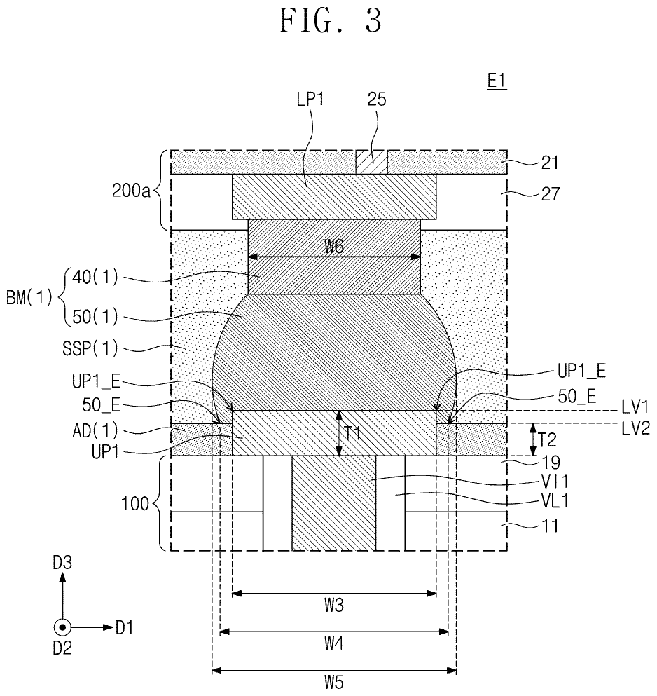

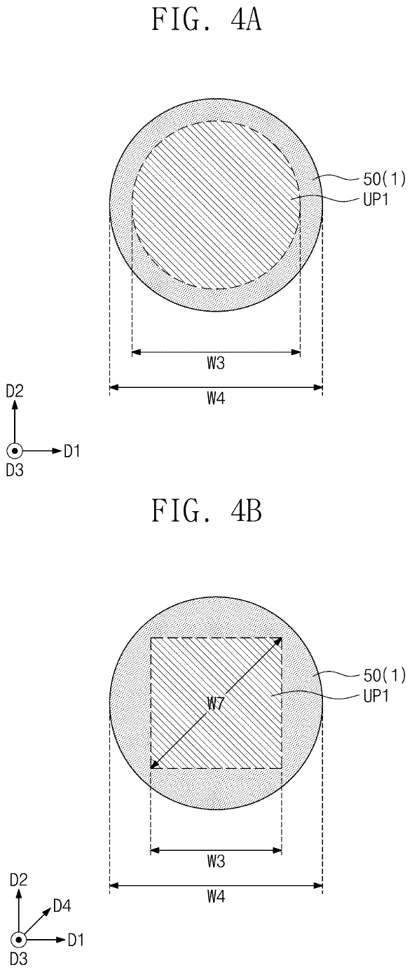

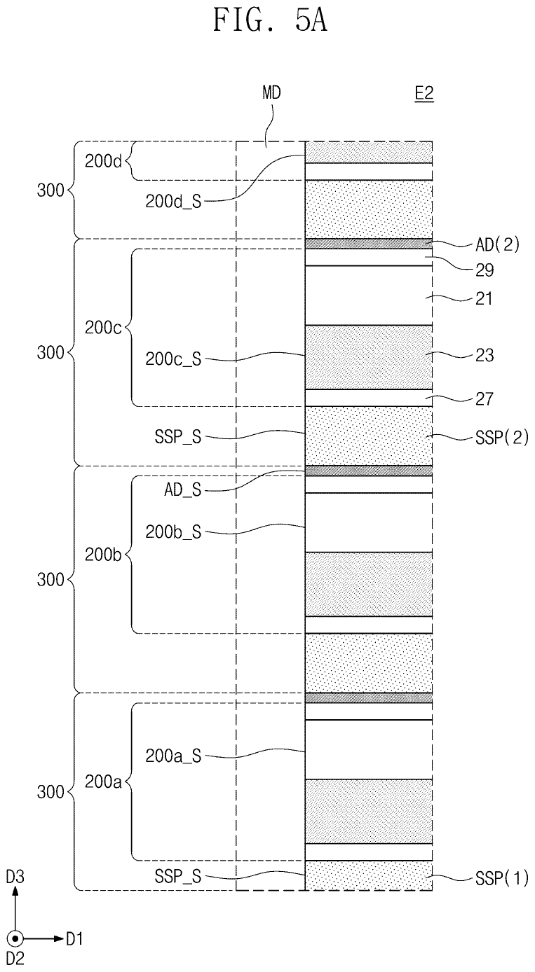

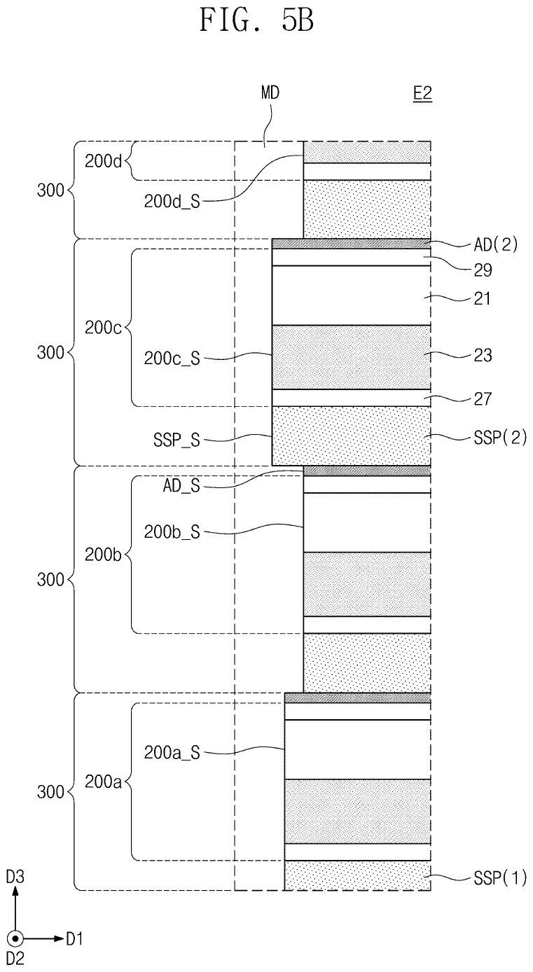

FIG. 3 is an enlarged view of portion ‘E1’ of FIG. 2. FIGS. 4A and 4B illustrate plan views of a first upper conductive pad and a first solder pattern according to one or more embodiments of the disclosure. FIGS. 5A and 5B are enlarged views of portion ‘E2’ of FIG. 2.

Referring to FIGS. 2 and 3, a first thickness T1 of the first upper conductive pad UP1 of the first semiconductor chip 100 may be greater than a second thickness T2 of the first adhesive layer AD(1). For example, the first thickness T1 may be 1.2 to 1.5 times the second thickness T2.

The first upper conductive pad UP1 may have a first edge (or first edge portion) UP1_E inserted into the first bump structure BM(1). That is, the first edge UP1_E of the first upper conductive pad UP1 may be inserted into the first solder pattern 50(1). The first solder pattern 50(1) may have a second edge (or second edge portion) 50_E adjacent to the first substrate 11 of the first semiconductor chip 100. The second edge 50_E may be spaced apart from the first edge UP1_E in the first direction D1. The second edge 50_E may be positioned at a lower level than the first edge UP1_E. That is, a first level LV1 of the first edge UP1_E may be higher than a second level LV2 of the second edge 50_E in a third direction D3 perpendicular to the first substrate 11. While the term “edge” is used to refer to a portion of the first edge UP1_E that is inserted into the first bump structure BM(1) when viewed in a cross-section, this term should be understood as including a portion of one or more surfaces of the first edge UP1_E that are inserted into the first bump structure BM(1). For example, the first edge UP1_E may include an upper surface and portions of side surfaces of the first edge UP1_E that are inserted into the first bump structure BM(1). While the term “edge” may be interchangeably used with “edge portion,” for convenience of explanation, the term “first edge” or “second edge” w ill be used in the below descriptions.

The first upper conductive pad UP1 may have a third width W3 in the first direction D1. A distance between the second edges 50_E of the first solder pattern 50(1) in the first direction D1 may have a fourth width W4. The first solder pattern 50(1) in the first direction D1 may have a maximum width of a fifth width W5. The fourth width W4 may be greater than the third width W3. The fifth width W5 may be greater than the fourth width W4. The first metal pattern 40(1) may have a sixth width W6 in the first direction D1, and the sixth width W6 may be smaller than the fifth width W5.

The first adhesive layer AD(1) may extend to cover a sidewall of the first upper conductive pad UP1 that is not inserted into the first solder pattern 50(1). The second edge 50_E of the first solder pattern 50(1) may be in contact with the first adhesive layer AD(1).

An upper portion of the first upper conductive pad UP1 may be partially inserted into the first solder pattern 50(1), and thus, the first solder pattern 50(1) may protect the first upper conductive pad UP1. As the first adhesive layer AD(1) protects the sidewall of the first upper conductive pad UP1 that is not inserted into the first solder pattern 50(1), a void and/or a crack between the first upper conductive pad UP1 and the first solder pattern 50(1) may be prevented. As a result, a semiconductor package with improved reliability may be provided.

Referring to FIG. 4A, each of the first solder pattern 50(1) and the first upper conductive pad UP1 may have a circular shape when viewed in a plan view. The fourth width W4 of the first solder pattern 50(1) may be greater than the third width W3 of the first upper conductive pad UP1, in the first direction D1. For example, an area of an upper surface or a lower surface of the first upper conductive pad UP1 may be about 0.68 to about 0.89 times an area of a lower surface of the first solder pattern 50(1) where the second edge 50_E is disposed. Although not illustrated, a width of the second upper conductive pads UP2 of each of the second to fourth semiconductor chips 200a to 200c in the first direction D1 may be smaller than a width of the second solder pattern 50(2).

Referring to FIG. 4B, when viewed in a plan view, the first solder pattern 50(1) may have a circular shape, and the first upper conductive pad UP1 may have a square shape. A seventh width W7 of the first upper conductive pad UP1 in a fourth direction D4 crossing the first direction D1 and the second direction D2 may be smaller than the fourth width W4.

Referring to FIGS. 2, 5A and 5B, the second substrate 21, the second interlayer insulating layer 23, the second frontside protection layer 27, the second backside protection layer 29, the first or second bump protection layer SSP(1) or SSP(2), and the second adhesive layer AD(2) may constitute or be included in a first chip structure 300. In one embodiment, as in FIG. 5A, one sidewall SSP_S of the first bump protection layer SSP(1) and one sidewall AD_S of the second adhesive layer AD(2) may be aligned with one sidewall 200a_S of the second semiconductor chip 200a. One sidewall SSP_S of the second bump protection layer SSP(2) may be aligned with sidewalls 200b_S, 200c_S, and 200d_S of the corresponding third to fifth semiconductor chips 200b to 200d. One sidewalls of the first chip structures 300 may be aligned with each other.

Alternatively, in another embodiment, as illustrated in FIG. 5B, one sidewalls of the first chip structures 300 may not be aligned with each other but may be spaced apart.

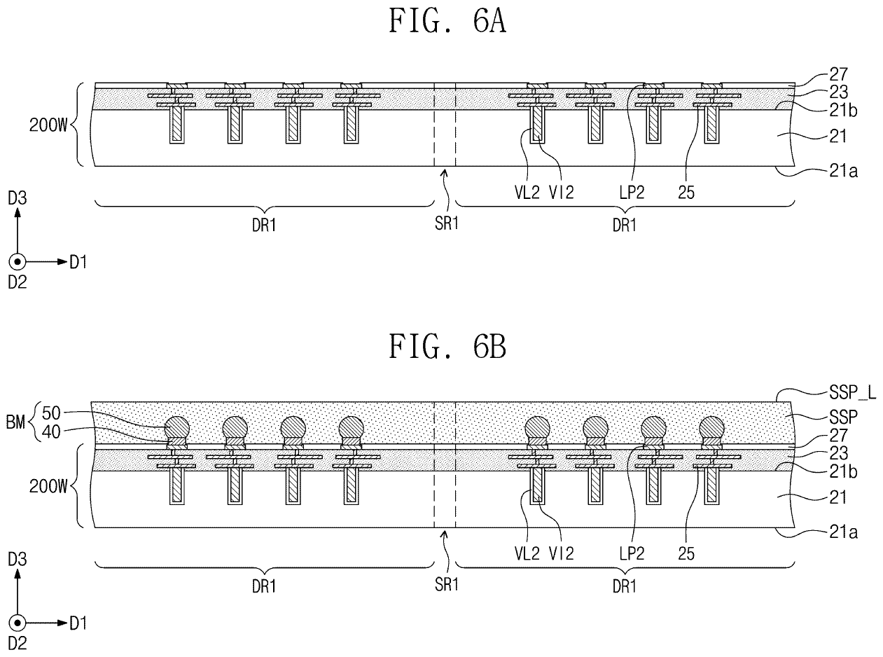

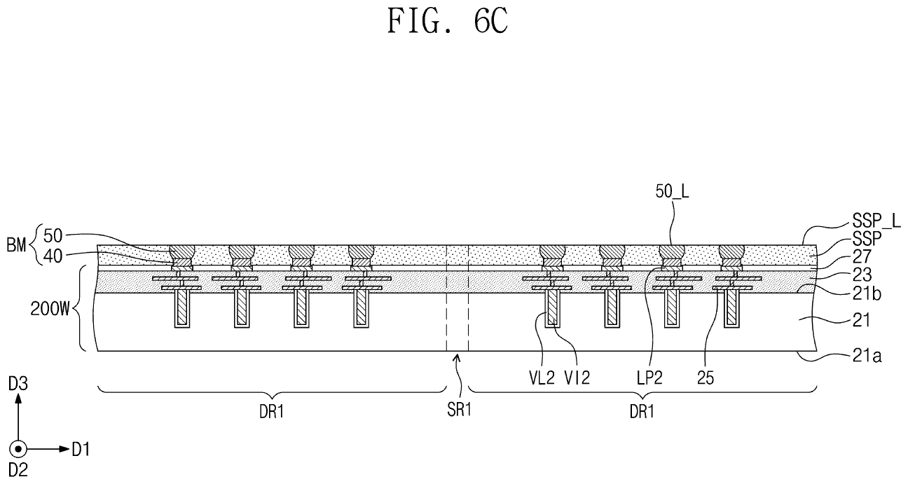

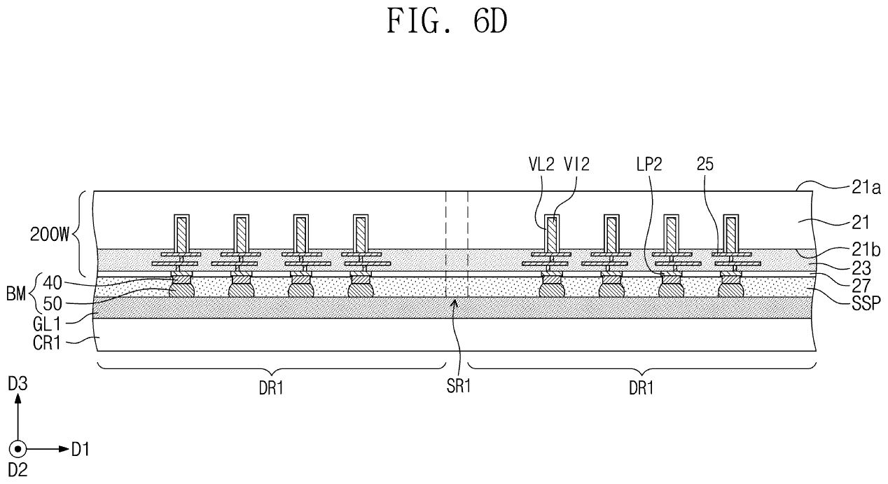

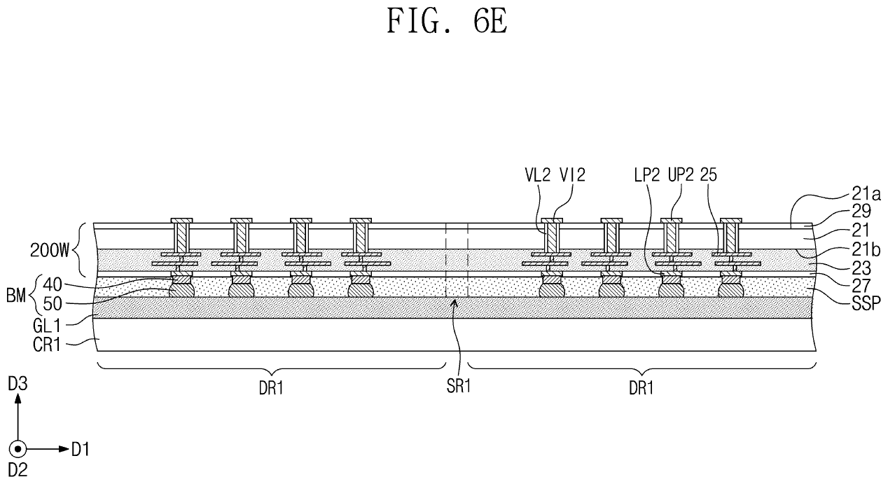

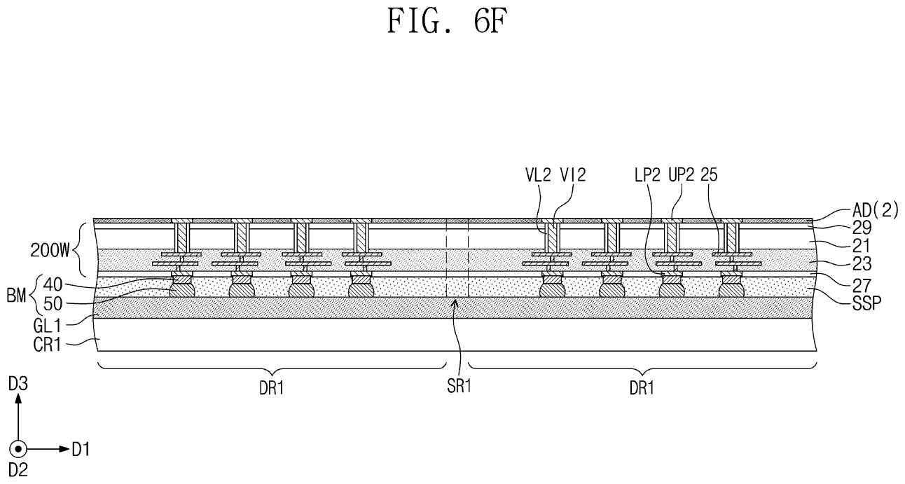

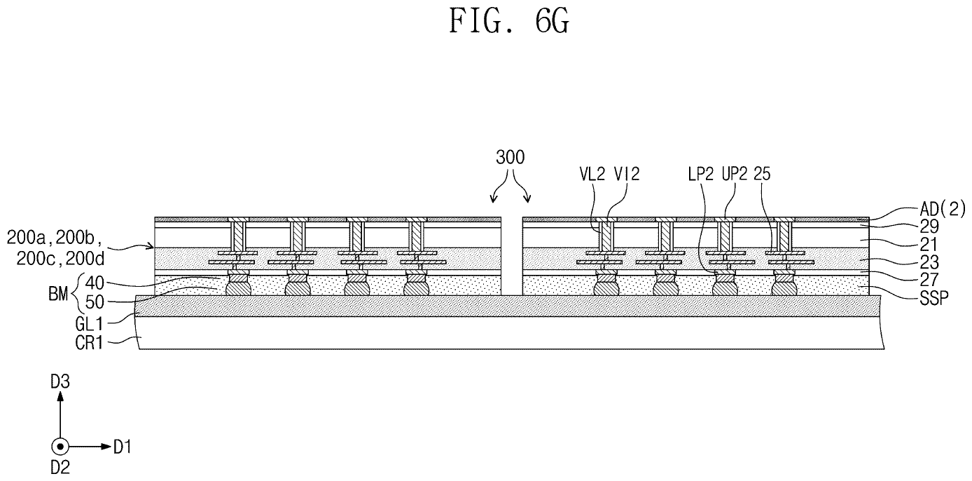

FIGS. 6A to 6G are cross-sectional views sequentially illustrating a process of manufacturing a first chip structure according to one or more embodiments of the disclosure. Hereinafter, any content that overlaps with what has been described above will be omitted.

Referring to FIGS. 2 and 6A, a second substrate wafer 200W is prepared. The second substrate wafer 200W may include a plurality of first chip regions DR1 and a first separation region SR1 therebetween. Each of the first chip regions DR1 of the second substrate wafer 200W may have a structure including the second to fifth semiconductor chips 200a to 200d described with reference to FIG. 2. The first separation region SR1 may be a scribe lane region.

The second substrate wafer 200W may include a second substrate 21. The second substrate 21 may include a second back surface 21a and a second front surface 21b that are opposite to each other. Transistors (not shown) and a second interlayer insulating layer 23 may be formed on the second front surface 21b. The second interlayer insulating layer 23 and the second substrate 21 may be etched to form a through hole, and a second via insulating layer VL2 and second through-vias VI2 may be formed in the through hole. Second wiring lines 25 may be formed on the second interlayer insulating layer 23, and a second frontside protection layer 27 and second lower conductive pads LP2 may be formed thereon.

Referring to FIG. 6B, bump structures BM may be bonded on the second lower conductive pads LP2. The bump structures BM may include a metal pattern 40 bonded to the second lower conductive pads LP2 and a solder pattern 50 bonded thereto. A bump protection layer SSP covering the bump structures BM and the second front surface 21b of the second substrate wafer 200W may be formed by a molding process.

Referring to FIG. 6C, a portion of a first surface SSP_L of the bump protection layer SSP and a portion of the bump structure BM may be removed by a grinding process to expose a second surface 50_L of the bump structure BM.

Referring to FIGS. 6D and 6E, the second substrate wafer 200W may be turned over, and the second substrate wafer 200W may be attached on a first carrier substrate CR1 by interposing a first carrier adhesive layer GL1 therebetween. The first carrier substrate CR1 may bean insulating substrate including glass or polymer, or a conductive substrate including metal. The first carrier adhesive layer GL1 may include an adhesive and/or thermosetting and/or thermoplastic and/or photocurable resin.

A back grinding process may be performed on the second back surface 21a of the second substrate 21 to partially remove the second substrate 21 and to expose the second via insulating layer VL2. A second backside protection layer 29 may be formed on the second back surface 21a of the second substrate 21, and the second via insulating layer VL2 may be removed by a chemical mechanical polishing (C M P) or an etch-back process to expose the second through-vias VI2. Second upper conductive pads UP2 may be formed on the second backside protection layer 29.

Referring to FIG. 6F, a second adhesive layer AD(2) covering sidewalls and the second back surface 21a of the second upper conductive pads UP2 may be formed by a coating and etching process.

Referring to FIGS. 2 and 6G, a dicing process may be performed to remove the first separation region SR1 to form a plurality of first chip structures 300. The dicing process may divide the second substrate wafer 200W into the plurality of first chip structures 300. The first chip structures 300 may include second to fifth semiconductor chips 200a to 200d. Thereafter, the first chip structures 300 may be separated from the first carrier adhesive layer GL1. The first chip structures 300 may be formed with the same width.

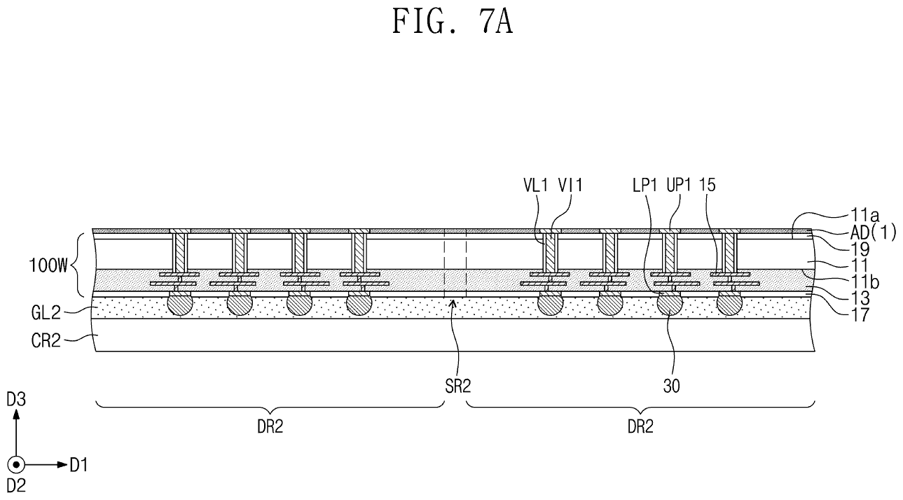

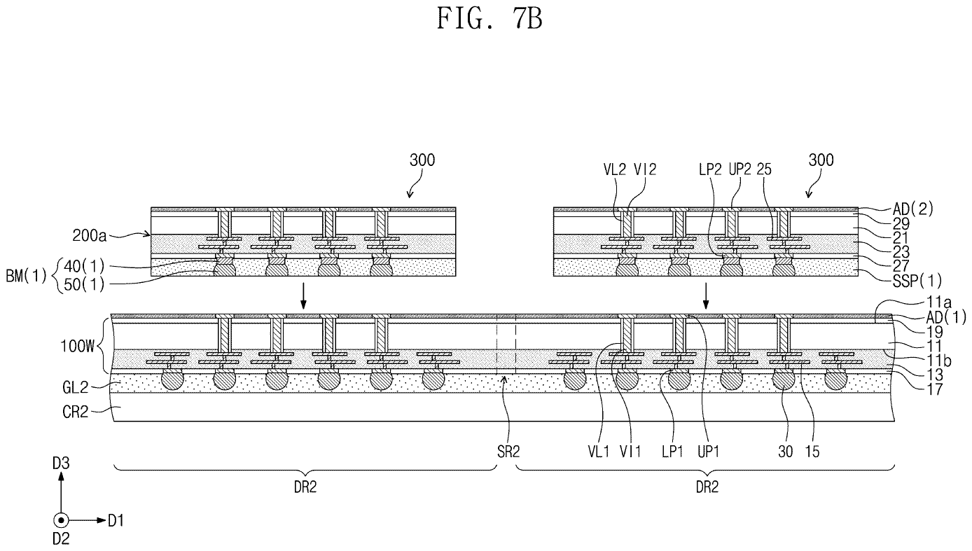

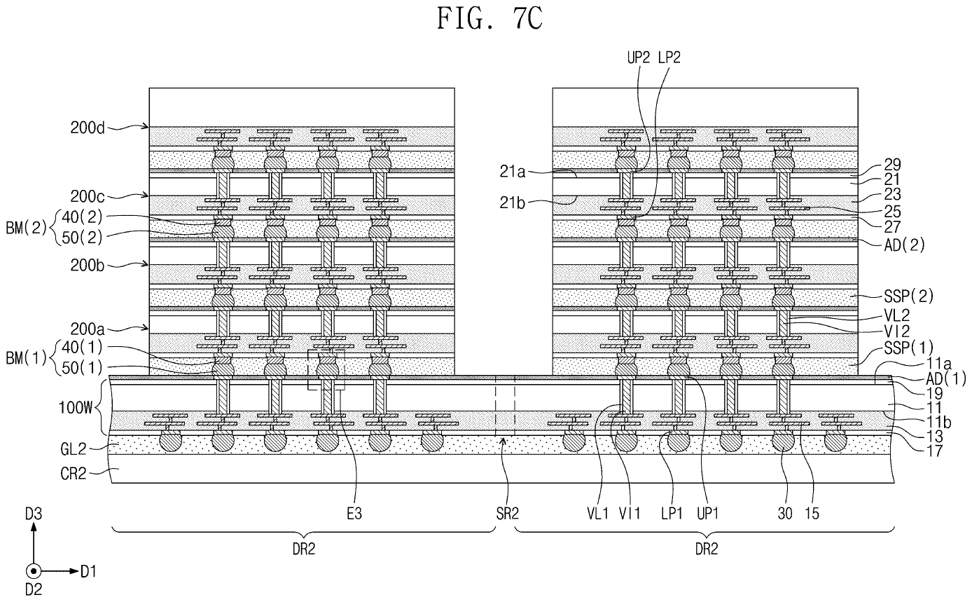

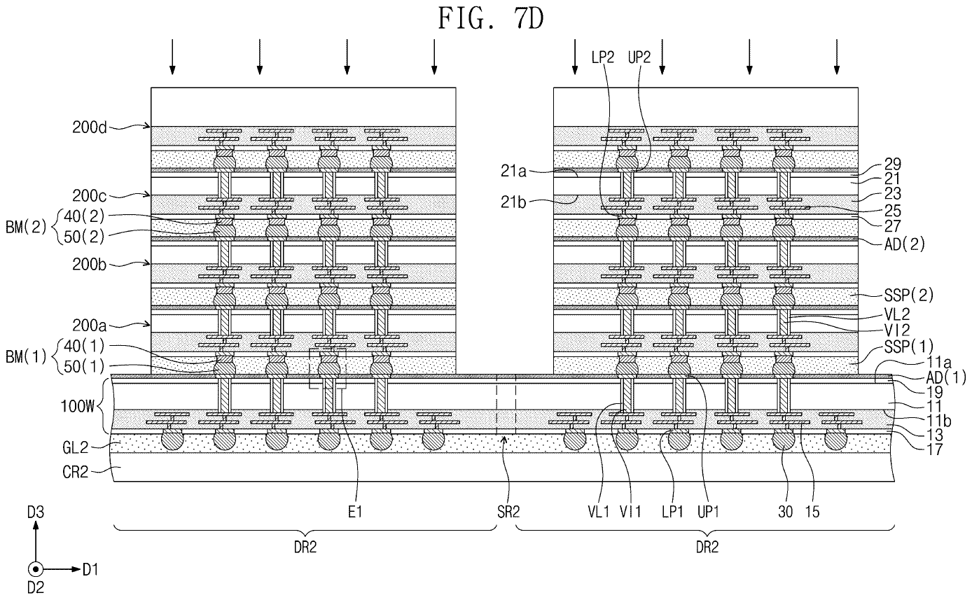

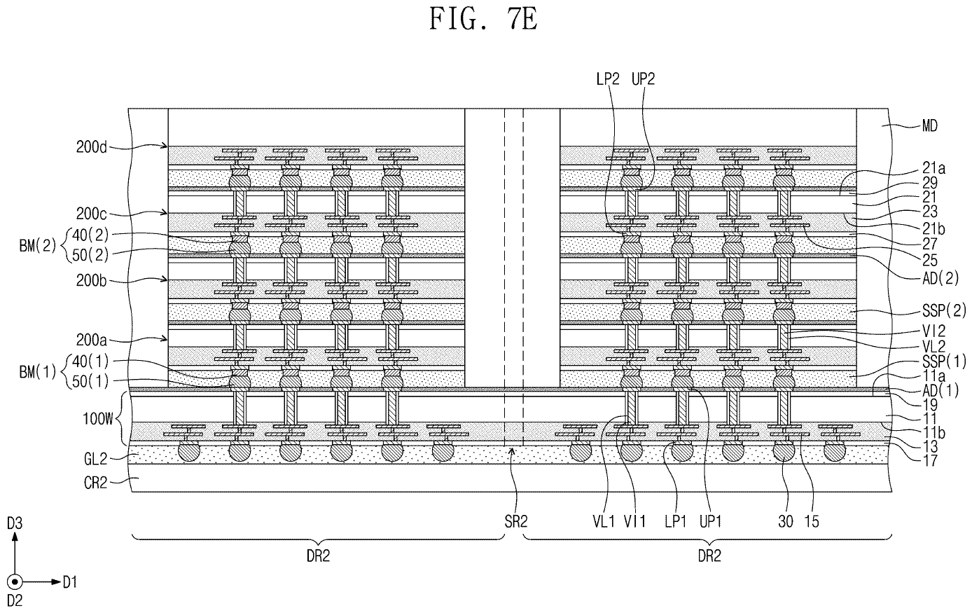

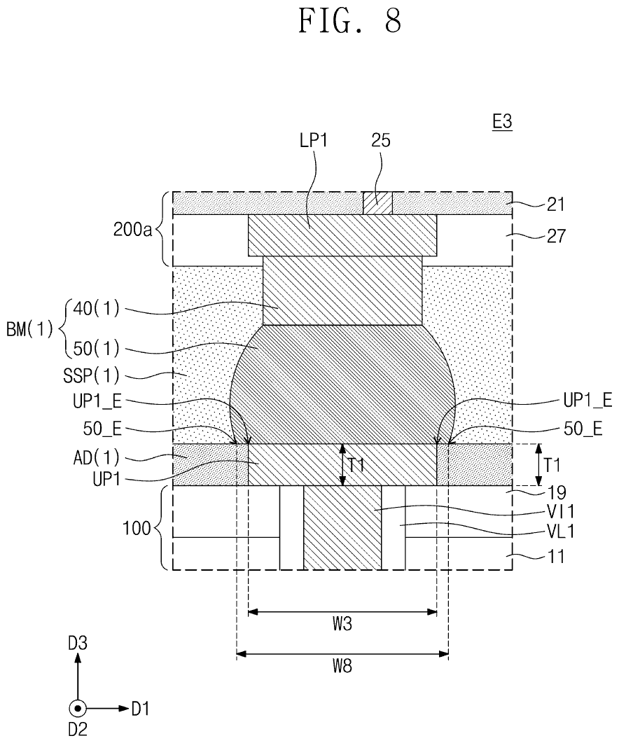

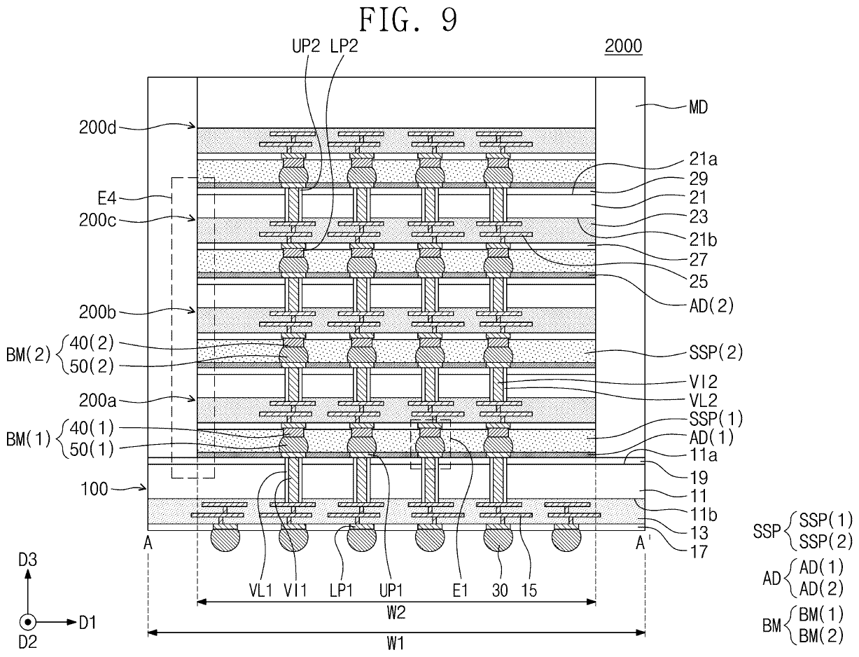

FIGS. 7A to 7E are cross-sectional views sequentially illustrating a process of manufacturing a semiconductor package of FIG. 2 according to one or more embodiments of the disclosure. FIG. 8 is an enlarged view of portion ‘E3’ of FIG. 7C.

Referring to FIG. 7A, a first substrate wafer 100W is prepared. The first substrate wafer 100W may have a plurality of second chip regions DR2 and a second separation region SR2 therebetween. Each of the second chip regions DR2 of the first substrate wafer 100W may have the structure of the first semiconductor chip 100 described with reference to FIG. 2. The second separation region SR2 may be a scribe lane region.

The first substrate wafer 100W may include a first substrate 11. The first substrate 11 may include a first back surface 11a and a first front surface 11b that are opposite to each other.

In the same or similar manner as described above, transistors (not shown), a first through-via VI1, a first via insulating layer VL1, first wiring lines 15, a first interlayer insulating layer 13, first upper conductive pads UP1, first lower conductive pads LP1, a first frontside protection layer 17, and a first backside protection layer 19 may be formed on the second chip regions DR2 of the first substrate 11. First connection members 30 may be bonded to the first lower conductive pads LP1. The first substrate wafer 100W may be placed such that the first connection members 30 face downward, and may be bonded by interposing a second carrier adhesive layer GL2 therebetween. Thereafter, a first adhesive layer AD(1) covering the sidewalls and the first back surface 11a of the first upper conductive pads UP1 may be formed by a coating and etching process.

Referring to FIGS. 6G, 7B and 7C, the first bump structure BM(1) and the second bump structure BM(2) may be identical or similar to each other. The first bump protection layer SSP(1) and the second bump protection layer SSP(2) may be identical or similar to each other.

One of the first chip structures 300 may be placed on the first substrate wafer 100W such that the first upper conductive pad UP1 overlaps the second surface 50_L of the first bump structure BM(1), and the first adhesive layer AD(1) on the first substrate wafer 100W is in contact with the first surface SSP_L of the first bump protection layer SSP(1).

A plurality of first chip structures 300 may be sequentially stacked on the first chip structure 300 such that the second upper conductive pad UP2 overlaps the second surface 50_L of the second bump structure BM(2), and the second adhesive layer AD(2) of the first chip structure 300 is in contact with the first surface SSP_L of the second bump protection layer SSP(2). Referring to FIG. 8, in this case, an upper surface of the first upper conductive pad UP1, an upper surface of the first adhesive layer AD(1) on the first substrate wafer 100W, the first edge UP1_E of the first upper conductive pad UP1, and the second edge 50_E of the first bump structure BM(1) may be positioned at the same level, and the first edge UP1_E and the second edge 50_E may be spaced apart from each other in the first direction D1. The first upper conductive pad UP1 and the first adhesive layer AD(1) may have the same first thickness T1.

Referring to FIG. 7D, a thermal compression process may be performed to bond the first chip structures 300 to the first substrate wafer 100W. In this process, as shown in FIG. 3, the first edge UP1_E of the first upper conductive pad UP1 may be inserted into the bump structure BM, and the second edge 50_E of the bump structure BM may be positioned at a lower level than the first edge UP1_E.

Referring to FIGS. 6C and 7D, the first and second bump protection layers SSP(1) and SSP(2) respectively covering the first and second bump structures BM(1) and BM(2) may be first formed, and the first chip structures 300 may be stacked on the first substrate wafer 100W, and then the thermocompression bonding process may be performed, thereby preventing the first and second solder patterns 50(1) and 50(2) from melting. Accordingly, deformation of the first and second bump structures BM(1) and BM(2) due to melting of the first and second solder patterns 50(1) and 50(2) that may occur during high-temperature bonding may be prevented. In addition, adhesion between the first solder pattern 50(1) and the first upper conductive pad UP1, the second solder pattern 50(2) and the second upper conductive pad UP2, the first bump protection layer SSP(1) and the first adhesive layer AD(1), and the second bump protection layer SSP(2) and the second adhesive layer AD(2) may be improved. As a result, reliability of the semiconductor package may be improved.

Referring to FIG. 7E, a molding process may be performed to form a molding member MD covering the upper surface of the first substrate wafer 100W and the first chip structures 300. Thereafter, the first substrate wafer 100W may be separated from the second carrier adhesive layer GL2, and a dicing process may be performed to remove the second separation region SR2, thereby forming a plurality of semiconductor packages 1000. Accordingly, the semiconductor packages 1000 of FIG. 1 may be formed.

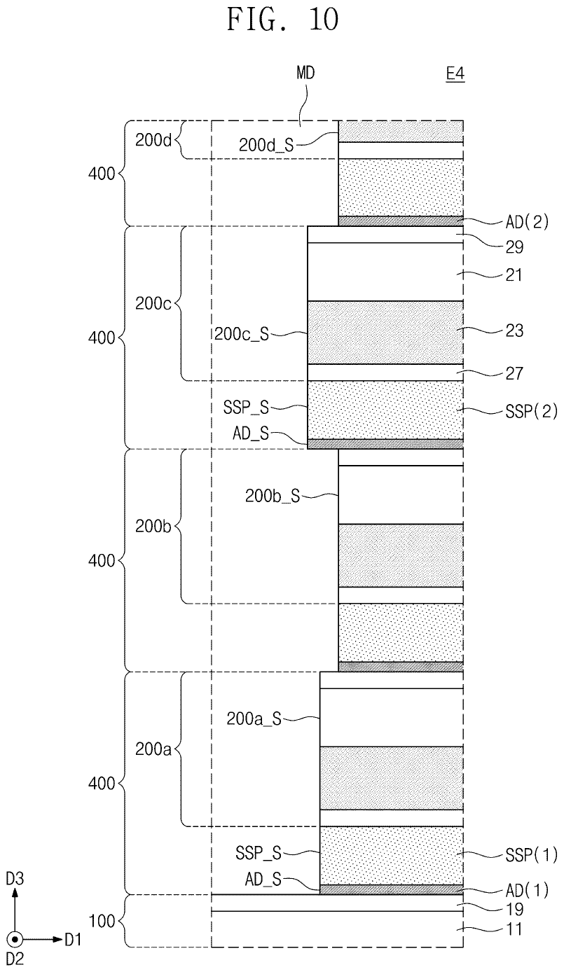

FIG. 9 is a cross-sectional view taken along line A-A′ of FIG. 1 according to one or more embodiments of the disclosure. FIG. 10 is an enlarged view of portion ‘E4’ of FIG. 9.

Referring to FIGS. 9 and 10, a second substrate 21, a second interlayer insulating layer 23, a second frontside protection layer 27, a second backside protection layer 29, a first or second bump protection layer SSP(1) or SSP(2), and a first or second adhesive layer AD(1) or AD(2) may constitute or be included in a second chip structure 400. The first adhesive layer AD(1) may have a second width W2 that is the same as the second semiconductor chip 200a in the first direction D1.

One sidewall SSP_S of the first bump protection layer SSP(1) and one sidewall AD_S of the first adhesive layer AD(1) may be aligned with one sidewall of the second semiconductor chip 200a. One sidewall SSP_S of the second bump protection layer SSP(2) may be aligned with one sidewalls 200b_S, 200c_S, and 200d_S of the corresponding third to fifth semiconductor chips 200b to 200d. The one sidewalls of two or more of the second chip structures 200 may not be aligned with each other and may be spaced apart from each other in the first direction D1. The other configurations may be the same or similar to those described with reference to FIGS. 1 to 5B.

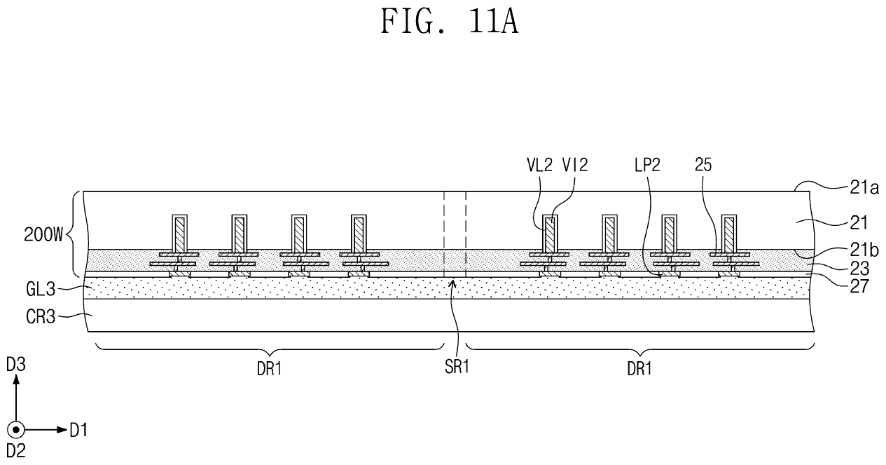

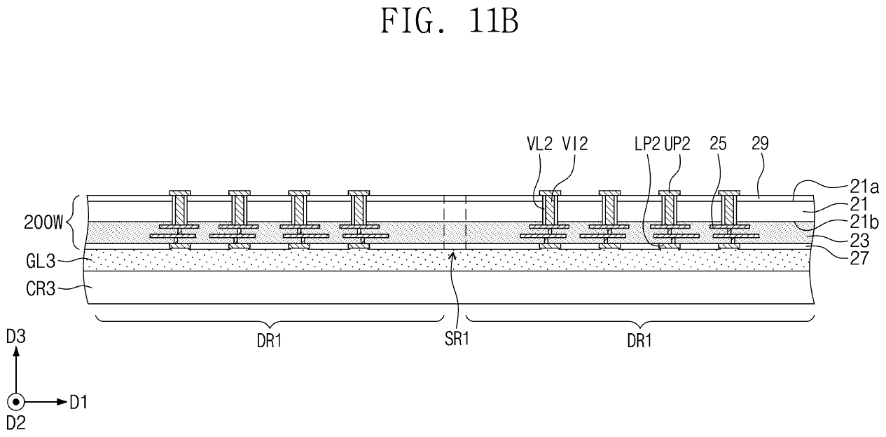

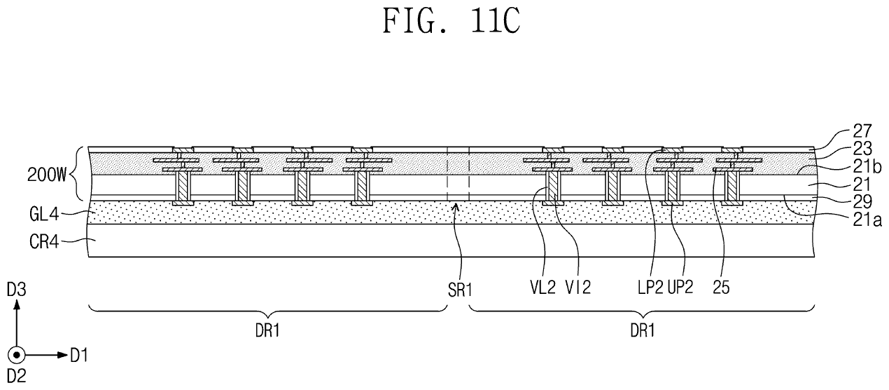

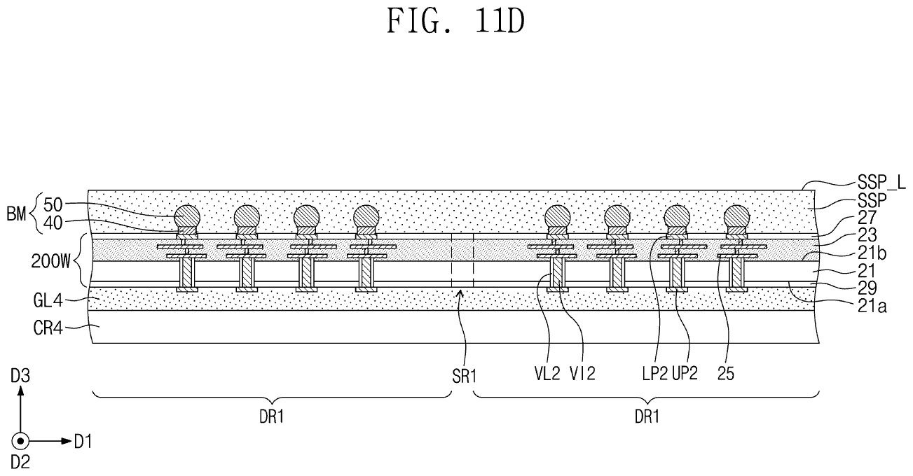

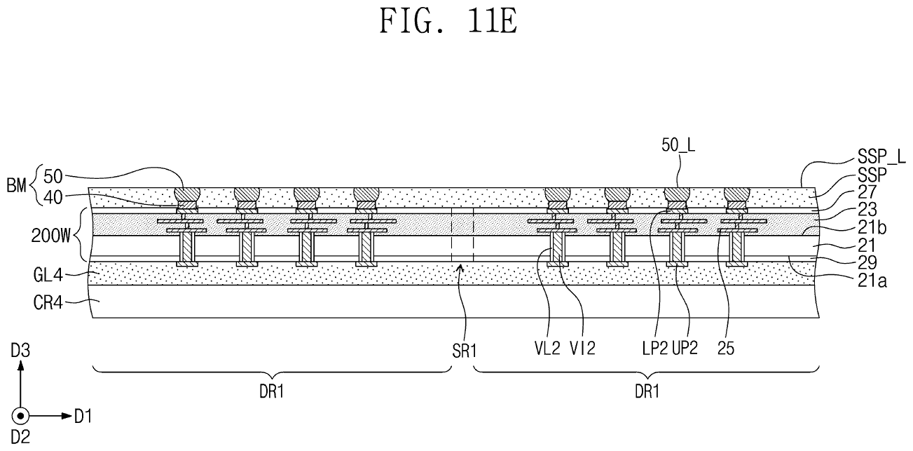

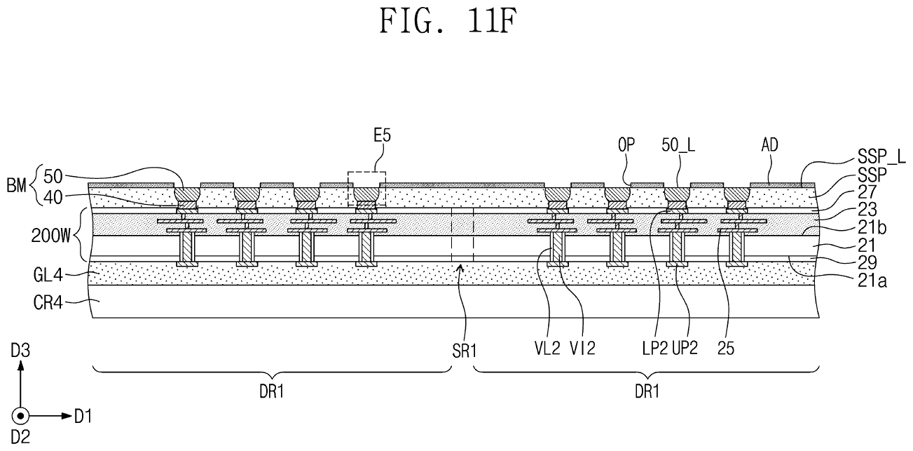

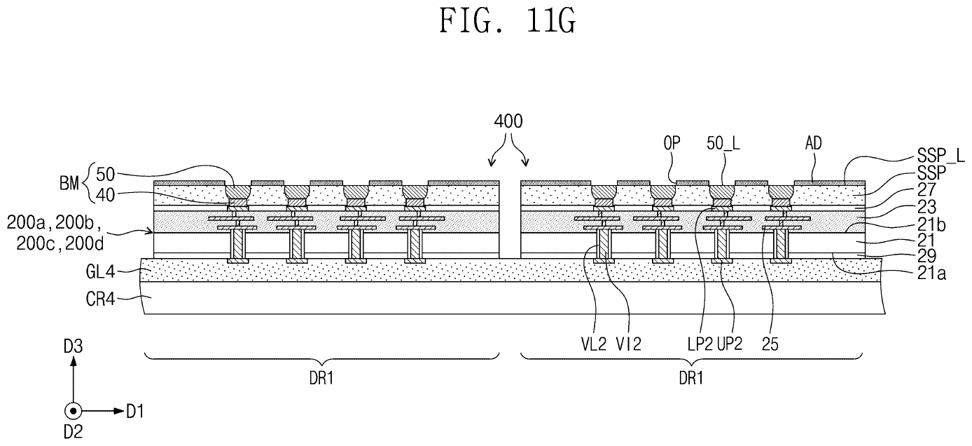

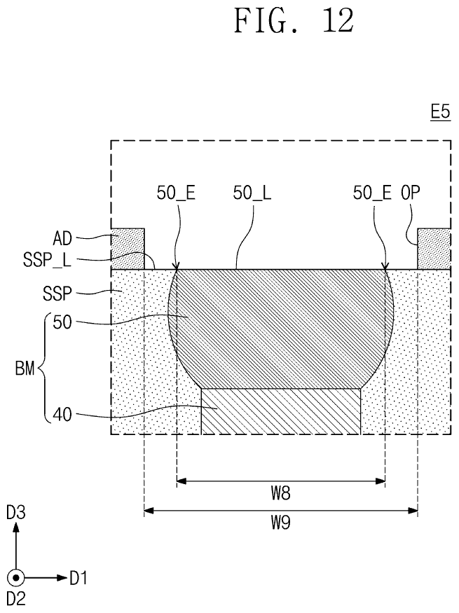

FIGS. 11A to 11G are cross-sectional views sequentially illustrating a process of manufacturing a second chip structure according to one or more embodiments of the disclosure. FIG. 12 is an enlarged view of portion ‘E5’ of FIG. 11F.

Referring to FIGS. 6A and 11A, the second substrate wafer 200W of FIG. 6A may be turned over, and the second substrate wafer 200W may be attached on a third carrier substrate CR3 by interposing a third carrier adhesive layer GL3 therebetween.

Referring to FIGS. 6E and 11B, a back grinding process may be performed on the second back surface 21a of the second substrate 21 in the same or similar manner as in FIG. 6E, thereby partially removing the second substrate 21 and forming a second backside protection layer 29 and second upper conductive pads UP2.

Referring to FIG. 11C, the second substrate wafer 200W may be turned over and the second substrate wafer 200W may be attached on a fourth carrier substrate CR4 by interposing a fourth carrier adhesive layer GL4 therebetween. The third carrier adhesive layer GL3 and the third carrier substrate CR3 may be removed.

Referring to FIG. 11D, bump structures BM may be bonded on the second lower conductive pads LP2. Each of the bump structures BM may include a metal pattern 40 bonded to the second lower conductive pads LP2 and a solder pattern 50 bonded thereto. A bump protection layer SSP covering the bump structures BM and the second front surface 21b of the second substrate wafer 200W may be formed by a molding process.

Referring to FIG. 11E, a portion of the first surface SSP_L of the bump protection layer SSP and a portion of the bump structure BM may be removed by a grinding process to expose a second surface 50_L of the bump structure BM.

Referring to FIGS. 11F and 12, an adhesive layer AD covering the bump protection layer SSP may be formed by a coating and etching process. The adhesive layer AD may have an opening OP exposing the second surface 50_L of the bump structure BM. The opening OP may expose a second edge 50_E of the bump structure BM. A portion of the first surface SSP_L of the bump protection layer SSP adjacent to the bump structure BM may be exposed. A distance between the second edges 50_E of the bump structures BM in the first direction D1 may have an eighth width W8. A distance between the openings OP in the first direction D1 may have a ninth width W9 that is greater than the eighth width W8.

Referring to FIGS. 2 and 11G, a dicing process may be performed to remove the first separation region SR1, thereby forming a plurality of second chip structures 400. The second chip structures 400 may include second to fifth semiconductor chips 200a to 200d. Thereafter, the second chip structures 400 may be separated from the fourth carrier adhesive layer GL4. The second chip structures 400 may be formed with the same width.

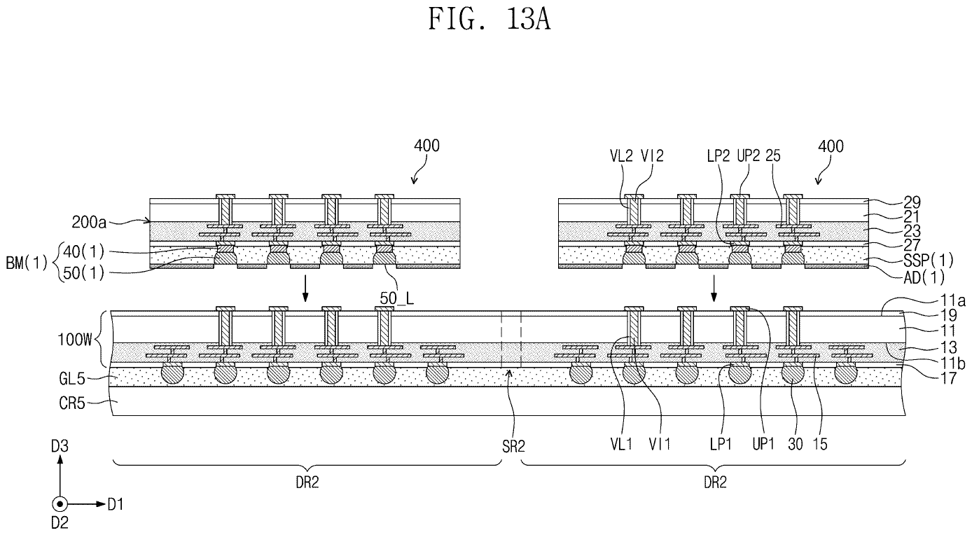

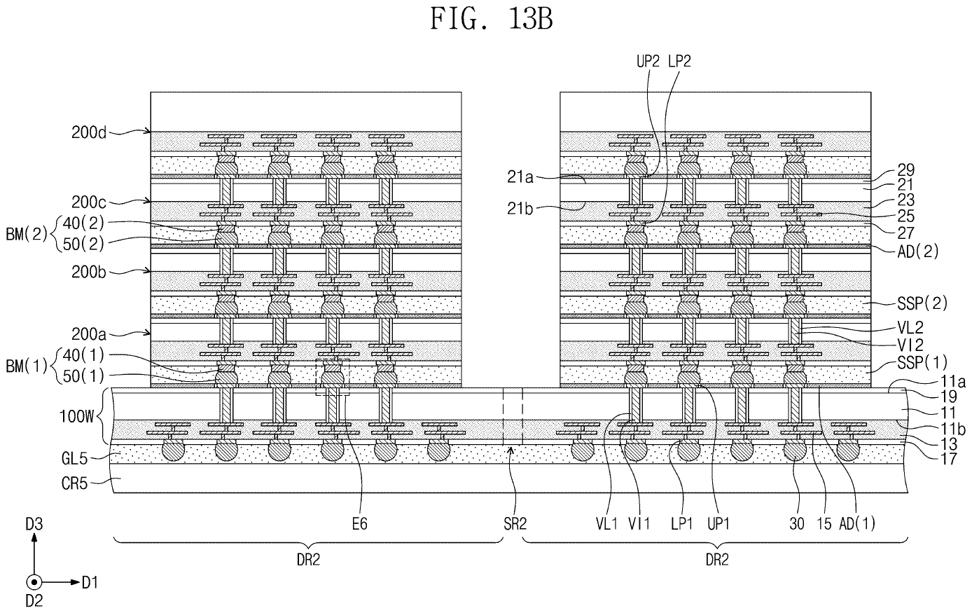

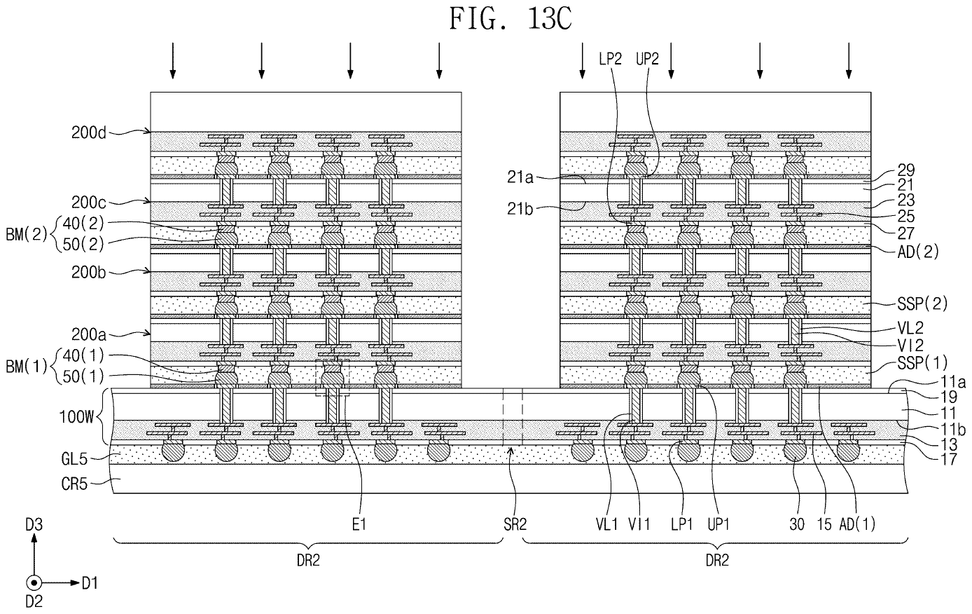

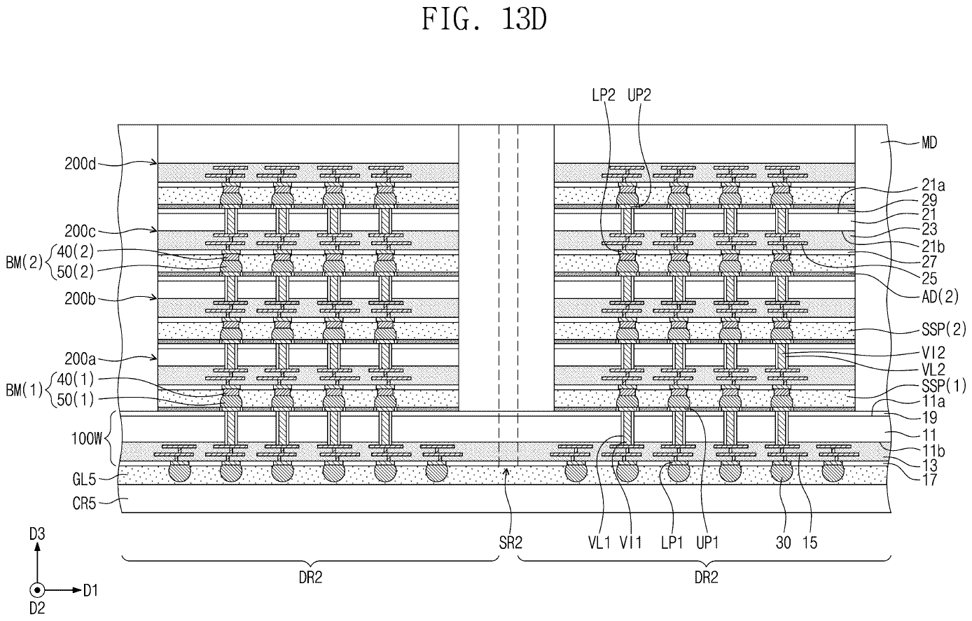

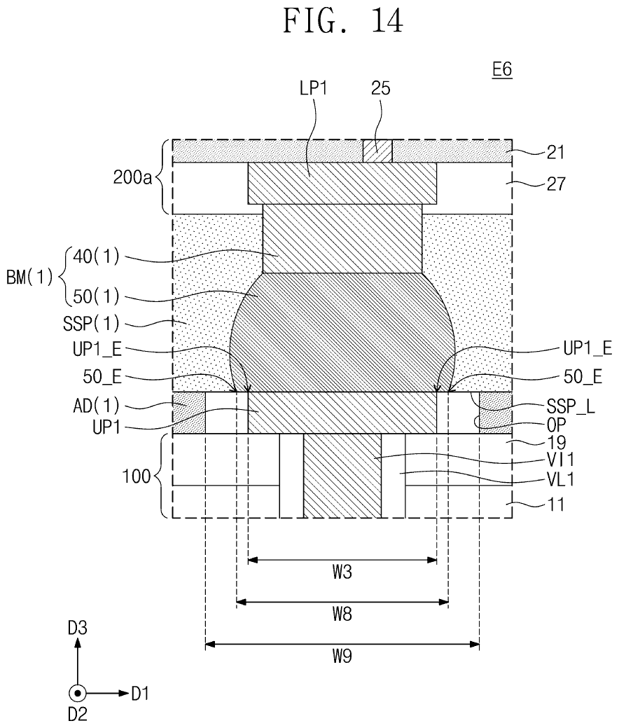

FIGS. 13A to 13D are cross-sectional views sequentially illustrating a process for manufacturing a semiconductor package of FIG. 9 according to one or more embodiments of the disclosure. FIG. 14 is an enlarged view of portion ‘E6’ of FIG. 13B.

Referring to FIGS. 2 and 13A, a first substrate wafer 100W is prepared. The first substrate wafer 100W may have a plurality of second chip regions DR2 and a second separation region SR2 therebetween. Each of the second chip regions DR2 of the first substrate wafer 100W may have the structure of the first semiconductor chip 100 described with reference to FIG. 2. The second separation region SR2 may be a scribe lane region.

The first substrate wafer 100W may include a first substrate 11. The first substrate 11 may include a first back surface 11a and a first front surface 11b that are opposite to each other.

In the same or similar manner as described above, transistors (not shown), a first through-via VI1, a first via insulating layer VL1, first wiring lines 15, a first interlayer insulating layer 13, first upper conductive pads UP1, first lower conductive pads LP1, a first frontside protection layer 17, and a first backside protection layer 19 may be formed on the second chip regions DR2 of the first substrate 11. First connection members 30 may be bonded to the first lower conductive pads LP1. The first substrate wafer 100W may be placed such that the first connection members 30 face downward, and may be bonded to a fifth carrier substrate CR5 by interposing a fifth carrier adhesive layer GL5 therebetween.

Referring to FIGS. 11G, 13A, and 13B, the bump structure BM may include a first bump structure BM(1) and a second bump structure BM(2). The first bump structure BM(1) and the second bump structure BM(2) may be identical or similar to each other. The bump protection layer SSP may include a first bump protection layer SSP(1) and a second bump protection layer SSP(2). The first bump protection layer SSP(1) and the second bump protection layer SSP(2) may be identical or similar to each other.

One of the second chip structures 400 may be placed on the first substrate wafer 100W such that the first upper conductive pad UP1 overlaps the second surface 50_L of the first bump structure BM(1), and the first backside protection layer 19 on the first substrate wafer 100W is in contact with the first adhesive layer AD(1).

A plurality of second chip structures 400 may be sequentially stacked on the second chip structure 400 such that the second upper conductive pad UP2 overlaps the second surface 50_L of the second bump structure BM(2), and the second adhesive layer AD(2) of the second chip structure 400 is in contact with the second backside protection layer 29 of the second chip structure 400. Referring to FIGS. 12 and 14, in this case, an upper surface of the first upper conductive pad UP1, the first surface SSP_L of the first bump protection layer SSP(1), the first edge UP1_E of the first upper conductive pad UP1, and the second edge 50_E of the first bump structure BM(1) may be positioned at the same level, and the first edge UP1_E and the second edge 50_E may be spaced apart from each other in the first direction D1. A third width W3 of the first upper conductive pad UP1 in the first direction D1 may be smaller than an eighth width W8 which is a distance between the second edges 50_E. A distance between the openings OP in the first direction D1 may have a ninth width W9 which is greater than the eighth width W8.

Referring to FIG. 13C, a thermal compression process may be performed to bond the second to fifth semiconductor chips 200a to 200d to the first substrate wafer 100W. In this process, as shown in FIG. 3, the first edge UP1_E of the first upper conductive pad UP1 may be inserted into the bump structure BM, and the second edge 50_E of the bump structure BM may be positioned at a lower level than the first edge UP1_E.

Referring to FIGS. 11E and 13C, the first and second bump protection layers SSP(1) and SSP(2) respectively covering the first and second bump structures BM(1) and BM(2) may be first formed, the second chip structures 400 may be stacked on the first substrate wafer 100W, and then the thermocompression bonding process may be performed, thereby preventing the first and second solder patterns 50(1) and 50(2) from melting. Accordingly, deformation of the first and second bump structures BM(1) and BM(2) due to melting of the first and second solder patterns 50(1) and 50(2) that may occur during high-temperature bonding may be prevented. In addition, adhesion between the first solder pattern 50(1) and the first upper conductive pad UP1, the second solder pattern 50(2) and the second upper conductive pad UP2, the first bump protection layer SSP(1) and the first adhesive layer AD(1), and the second bump protection layer SSP(2) and the second adhesive layer AD(2) may be improved. As a result, reliability of the semiconductor package may be improved.

Referring to FIG. 13D, a molding process may be performed to form a molding member MD covering an upper surface of the first substrate wafer 100W and the second chip structures 400. Thereafter, the first substrate wafer 100W may be separated from the fifth carrier adhesive layer GL5, and a dicing process may be performed to remove the second separation region SR2, thereby forming a plurality of semiconductor packages 2000. Accordingly, the semiconductor packages 2000 of FIG. 9 may be formed.

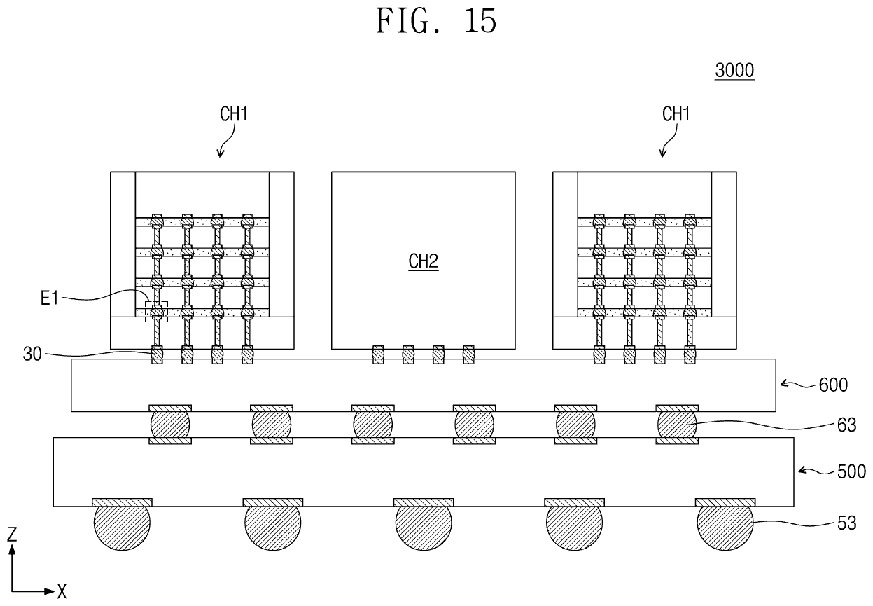

FIG. 15 is a cross-sectional view of a semiconductor package according to one or more embodiments of the disclosure.

Referring to FIG. 15, a semiconductor package 3000 according to one or more embodiments may include a package substrate 500, an interposer substrate 600 disposed on the package substrate 500, and first semiconductor structures CH1 and second semiconductor structures CH2 disposed on the interposer substrate 600. The package substrate 500 may be, for example, a double-sided or multi-layer printed circuit board. The interposer substrate 600 may include, for example, silicon. The first semiconductor structures CH1 and the second semiconductor structures CH2 may be disposed in parallel in a fifth direction X on the interposer substrate 600. The interposer substrate 600 may include internal wiring lines (not shown) connecting the first semiconductor structures CH1 and the second semiconductor structures CH2.

The first semiconductor structures CH1 may be connected to the interposer substrate 600 by first connection members 30. The first semiconductor structures CH1 may be identical or similar to the semiconductor package 1000 described with reference to FIGS. 1 to 5B. Alternatively, the first semiconductor structures CH1 may be identical or similar to the semiconductor package 2000 described with reference to FIGS. 9 and 10. An enlarged view of portion ‘E1’ in FIG. 15 may correspond to FIG. 3.

The second semiconductor structure CH2 may be an application specific integrated circuit (AIC) chip or a system on chip. The second semiconductor structure CH2 may also be referred to as a host, an application processor (AP), etc. Alternatively, the second semiconductor structure CH2 may be a semiconductor chip identical or similar to the first semiconductor structure CH1. The second semiconductor structure CH2 may be connected to the interposer substrate 600 by the first connection members 30.

The interposer substrate 600 may be bonded to the package substrate 500 by second connection members 63. Third connection members 53 may be bonded to a bottom of the package substrate 500. The first to third connection members 30, 53, and 63 may include at least one of a copper bump, a copper pillar, and a solder ball.

In the semiconductor package according to the disclosure, a portion of the upper portion of the conductive pad of the semiconductor chip disposed at a lower portion is inserted into the solder pattern, and thus the solder pattern may protect the conductive pad. Therefore, a void and/or a crack between the conductive pad and the solder pattern may be prevented. As a result, the semiconductor package with the improved reliability may be provided.

In the method of manufacturing the semiconductor package according to the disclosure, deformation of the bump structures due to melting of the solder pattern that may occur during high-temperature bonding may be prevented. As a result, the reliability of the semiconductor package may be improved.

While example embodiments are described above, a person skilled in the art would understand that many modifications and variations are made without departing from the spirit and scope of the disclosure defined in the following claims. Accordingly, the example embodiments of the disclosure should be considered in all respects as illustrative and not restrictive, with the spirit and scope of the disclosure being indicated by the appended claims and their equivalents.

What is claimed is:

1. A semiconductor package comprising:
a first semiconductor chip and a second semiconductor chip sequentially stacked;
a first bump structure between the first semiconductor chip and the second semiconductor chip and connecting the first semiconductor chip and the second semiconductor chip;
a first bump protection layer extending in a first direction between the first semiconductor chip and the second semiconductor chip and covering a side surface of the first bump structure; and
a first adhesive layer between the first bump protection layer and the first semiconductor chip,
wherein the first semiconductor chip includes a first upper conductive pad having a first edge portion inserted into the first bump structure,
wherein the first adhesive layer extends to cover a sidewall of the first upper conductive pad that is not inserted into the first bump structure, and
wherein a first thickness of the first upper conductive pad is greater than a second thickness of the first adhesive layer.

2. The semiconductor package of claim 1, wherein the first thickness is 1.2 to 1.5 times the second thickness.

3. The semiconductor package of claim 1, wherein the first semiconductor chip has a first width in the first direction,
wherein the second semiconductor chip has a second width in the first direction, and
wherein the first width is greater than the second width.

4. The semiconductor package of claim 3, wherein the first adhesive layer has a width in the first direction that is same as the first width of the first semiconductor chip.

5. The semiconductor package of claim 3, wherein the first adhesive layer has a width in the first direction that is same as the second width of the second semiconductor chip.

6. The semiconductor package of claim 3, wherein the first bump protection layer has a width in the first direction that is same as the second width of the second semiconductor chip, and
wherein one sidewall of the first bump protection layer is aligned with one sidewall of the second semiconductor chip.

7. The semiconductor package of claim 1, wherein the first bump structure includes:
a first solder pattern on the first upper conductive pad; and
a first metal pattern on the first solder pattern,
wherein the first edge portion of the first upper conductive pad is inserted into the first solder pattern.

8. The semiconductor package of claim 7, wherein the first solder pattern has a second edge portion adjacent to the first semiconductor chip,
wherein the second edge portion is spaced apart from the first edge portion in the first direction, and
wherein the second edge portion is positioned at a lower level than that of the first edge portion.

9. The semiconductor package of claim 1, wherein the first adhesive layer includes at least one of an epoxy resin, an acrylic polymer, and silicone.

10. The semiconductor package of claim 1, wherein the first bump protection layer includes at least one of an epoxy resin, an insulating resin, and a thermosetting resin.

11. The semiconductor package of claim 1, wherein the first semiconductor chip includes:
a first substrate including a first front surface and a first back surface that are opposite to each other;
first wiring lines on the first front surface;
a first interlayer insulating layer covering the first wiring lines;
a first backside protection layer covering the first back surface; and
a first through-via penetrating the first substrate and the first backside protection layer,
wherein the first upper conductive pad is disposed on the first back surface and is connected to a corresponding first through-via, and
wherein the first adhesive layer covers the first backside protection layer.

12. The semiconductor package of claim 1, further comprising:
a third semiconductor chip, a fourth semiconductor chip, and a fifth semiconductor chip sequentially stacked on the second semiconductor chip;
a second bump structure between the second semiconductor chip and the third semiconductor chip and connecting the second semiconductor chip and the third semiconductor chip;
a second bump protection layer extending in the first direction between the second semiconductor chip and the third semiconductor chip and covering the second bump structure; and
a second adhesive layer between the second bump protection layer and the second semiconductor chip.

13. A semiconductor package comprising:
a first semiconductor chip and a second semiconductor chip sequentially stacked;
a first bump protection layer between the first semiconductor chip and the second semiconductor chip and extending in a first direction parallel to a first substrate;
a first bump structure between the first semiconductor chip and the second semiconductor chip and connecting the first semiconductor chip and the second semiconductor chip by penetrating the first bump protection layer; and
a first adhesive layer between the first bump protection layer and the first semiconductor chip,
wherein the first semiconductor chip includes the first substrate including a first front surface and a first back surface that are opposite to each other, a first upper conductive pad on the first back surface, and a first lower conductive pad on the first front surface,
wherein the second semiconductor chip includes a second substrate including a second front surface and a second back surface that are opposite to each other, and a second lower conductive pad on the second front surface,
wherein the first bump structure includes a first solder pattern connected to the first upper conductive pad, and a first metal pattern on the first solder pattern and connected to the second lower conductive pad,
wherein a first edge portion of the first upper conductive pad is inserted into the first solder pattern, and
wherein a second edge portion of the first solder pattern adjacent to the first substrate is spaced apart from the first edge portion in the first direction and is positioned at a lower level than that of the first edge portion.

14. The semiconductor package of claim 13, wherein each of the first semiconductor chip and the first adhesive layer has a first width in the first direction,
wherein the second semiconductor chip has a second width in the first direction, and
wherein the first width is greater than the second width.

15. The semiconductor package of claim 14, further comprising:
a third semiconductor chip, a fourth semiconductor chip, and a fifth semiconductor chip sequentially stacked on the second semiconductor chip and having the second width;
a second bump structure connecting the second semiconductor chip and the third semiconductor chip;
a second bump protection layer extending in the first direction between the second semiconductor chip and the third semiconductor chip and covering the second bump structure; and
a second adhesive layer between the second bump protection layer and the second semiconductor chip,
wherein the second bump structure includes a second solder pattern penetrating the second bump protection layer, and a second metal pattern on the second solder pattern.

16. The semiconductor package of claim 15, wherein each of the first bump protection layer between the first semiconductor chip and the second semiconductor chip and the first adhesive layer on the second semiconductor chip has the second width in the first direction, and
wherein one sidewall of the first bump protection layer and one sidewall of the first adhesive layer are aligned with one sidewall of the second semiconductor chip.

17. The semiconductor package of claim 13, wherein a width of the first solder pattern in the first direction is greater than a width of the first metal pattern in the first direction.

18. A semiconductor package comprising:
semiconductor chips sequentially stacked;
a molding member covering the semiconductor chips;
a bump structure between the semiconductor chips and connecting the semiconductor chips;
a bump protection layer covering a side surface of the bump structure; and
an adhesive layer between the bump protection layer and a corresponding semiconductor chip,
wherein each of the semiconductor chips includes:
a substrate including a front surface and a back surface opposite to each other;
a lower conductive pad on the front surface;
a through-via penetrating the substrate; and
an upper conductive pad on the back surface and connected to the through-via,
wherein the bump structure connects the upper conductive pad and the lower conductive pad that are adjacent to each other,
wherein an upper portion of the upper conductive pad is partially inserted into the bump structure, and
wherein the bump protection layer includes at least one of an epoxy resin, an insulating resin, and a thermosetting resin.

19. The semiconductor package of claim 18, wherein the adhesive layer covers a sidewall of the upper conductive pad that is not inserted into the bump structure, and
wherein a first thickness of the upper conductive pad is greater than a second thickness of the adhesive layer.

20. The semiconductor package of claim 18, wherein the bump structure includes:
a solder pattern on the upper conductive pad; and
a metal pattern on the solder pattern,
wherein the upper portion of the upper conductive pad is partially inserted into the solder pattern, and
wherein a width of the solder pattern is greater than a width of the metal pattern.
